(19) United States
(12) Patent Application Publication
(10) Pub. No.: US 2001/0046558 A1
(43) Pub. Date: Nov. 29, 2001

(54) METHOD OF FABRICATING ELECTROLUMINESCENT DEVICE USING COORDINATION METAL COMPOUNDS ADDUCTED WITH ELECTRON DONOR LIGANDS AS PRECURSORS

(76) Inventors: YONG SHIN KIM, TAEJON (KR); SUN JIN YUN, TAEJON (KR); SANG HEE PARK, TAEJON (KR)

Correspondence Address: ANTONELLI TERRY STOUT & KRAUS, 1300 NORTH SEVENTEENTH STREET, SUITE 1800, ARLINGTON, VA, 22209

(21) Appl. No.: 09/408,514

(22) Filed: Sep. 30, 1999

(30) Foreign Application Priority Data
Sep. 30, 1998 (KR) 98-41260

(51) Int. Cl. C23C 16/00

(52) U.S. Cl. 427/255.29; 427/255.31; 427/255.32; 427/66

(57) ABSTRACT

A method of fabricating polycrystalline thin films based on IIA-group, IIIA-group, IVA-group, transition, or inner-transition metal sulfides or selenides by surface reaction and vapor phase reaction by using coordination metal compounds, adducted with neutral ligands and H₂Z (Z=S, Se) as precursors. The present invention also discloses a method of fabricating metal oxide polycrystalline thin films based on IIA-group, IIIA-group, IVA-group, transition, or inner-transition metal oxides by surface reaction and vapor phase reaction by using coordination metal compounds, adducted with neutral ligands as one of precursors. Main object of the present invention is to provide a method of fabricating high quality EL device using the above technique.

### BACKGROUND OF THE INVENTION

1. Field of the Invention

The present invention relates to a process of depositing metal compound thin films by an atomic layer deposition (ALD) method or chemical vapor deposition (CVD) using the coordination metal compounds adducted with electron donor ligands as precursors. The use of adducted metal compounds solves the problems caused by the use of conventional coordination metal compounds and improves the reaction stability. More particularly, it relates to deposition of metal compounds using a coordination compound adducted with neutral ligands as a precursor and a method of fabricating an electroluminescent (EL) device using the same.

2. Discussion of Related Art

When metal compound films are grown by CVD or ALD method using the coordination compounds, MXₙ, with ligands such as 2,2′,6,6′-tetramethyl-3,5-heptandione (thd), diethyldithiocarbamate (dedtc), MXₙ precursors are sensitive to the ambient air to be easily degraded and are affected by heat to be partly decomposed at the initial stage or in the middle of the processing.

There have been many cases of making precursors with suitable characteristics for applications by synthesizing new coordination metal compounds or by adducting an additive to overcome the instability of such coordination metal compounds. In U.S. Pat. No. 5,688,980, NR₃ or CI₂ in gaseous phase is flown into a vessel containing Pb(thd)₂ so that this vapor is introduced to a reactor. Then NR₃ (R=H, CH₃) or CI₂ molecules are adducted to Pb(thd)₂ to improve the reactivity at the time of depositing ferroelectric PbTiO films. These precursors show a remarkable improvement in volatility and thermal stability.

Prior art paper (by Hanninen T et al., Chemistry of Materials, V9, pp. 1234) describes another case using the Ca(thd)₂ complex adducted with tetraen (tetraethylenepentamine) as ligands at depositing CaS thin films by ALD technique. This adducted compound [Ca(thd)₂(tetraen)] has higher volatility and lower reaction temperature than those of Ca(thd)₂. However, its growth rate becomes a little decreased. This is explained as either because of steric constraints imposed by the tetraen ligand or because of the absorption of tetraen ligands liberated in the decomposition of [Ca(thd)₂(tetraen)] on surface. In both cases the coordination of bulky polydentate ligand reduces the reaction sites on surface, thus growth rate of film decreases. Generally, the ring-shaped macrocyclic ligand such as tetraen is known to be hardly decomposed compared to linear and small ligands. In the present invention, the coordination compounds are adducted with easily dissociative ligand.

As the main application of the present invention, an EL device with improved characteristics is obtained from the deposition of metal-doped II-VI group compound thin films using the precursors stabilized by electron donor ligands, MXₙ-L_{y}. In case that the present invention is carried out by travelingwave-type ALD, metal-doped II-VI group compound thin films are more uniformly grown when using MXₙ-L_{y} rather than using MXₙ precursors. A luminescent material used for the EL device comprised the host material selected from the II- (Zn, Ca, Sr, Ba, Mg) and VI-group (S, Se, O) compound semiconductors, ZnS, CaS, SrS, BaS, MgS, ZnₓCa₁₋ₓS, ZnₓSr₁₋ₓS, CaₓSr₁₋ₓS, etc., and the luminescent center elements such as transition, inner-transition, and IVA-group atoms. The electroluminescent device requires development of three primary color luminescent materials of high luminance red, green and blue to realize the high luminance full color display. There are ZnS:Mn of amber, ZnS:Tb of green as luminescent materials with a high luminescent efficiency for an EL device. Generally, ZnS.Mn devices with a red filter are used for red, or a red-emitting phosphor material such as ZnS:Sm,CI or CaS:Eu is used. ZnS:Tb is used for green. A blue-emitting phosphor material with appropriate luminance and color purity has not been developed yet, which is one of the biggest problems in the development of full color El display devices with high luminance.

Thin film deposition methods generally used for EL devices are physical vapor deposition and chemical vapor deposition. The former includes electron-beam evaporation, thermal evaporation, sputtering process, etc., and the latter includes ALD method, metal-organic CVD, etc. The chemical vapor deposition method needs proper reactive precursors, and those are halogen compounds, and thd-, or dedtc-coordination compounds. The thd-compounds are frequently employed. The thd-compounds of most metals such as Ca, Sr, Ba, Ga, Pb, Ce, Eu, Er, Tb, Mn, Cu, Sm, Gd, Tm, Yb, Lu, Y, etc. are available. The thd-compounds produce a sufficient amount of vapor at a relatively low temperature.

Alkaline-earth thiogallates thin films that are drawing much attention as a host material of blue-emitting phosphor material do not have a proper chemical state when they are grown by the ALD method. There are II-VI compounds such as CaS, ZnS, SrS, and thiogallates as available host materials of blue-emitting EL. As one of the blue phosphor, ZnS:Tm compounds have very low luminance of 1 cd/m² at 1 kHz and are of no utility. CaS or SrS can be used as a host material of the blue-emitting phosphor layer but are not suitable for fabrication of thin films with excellent reproducibility in large area.

The thin film characteristics strongly depend on the characteristics of precursors used for depositing thin films as well as on their own properties. The common precursors for metal sulfides grown by the ALD method are metal halide compounds and H₂S. The thd-compounds are easily degraded in the humid air so that it is difficult to form thin films with good uniformity and reproducibility. Particularly, Sr(thd)₂ reacts rapidly on moisture in the air to be denatured at its surface, and cannot generate sufficient vapor. In order to prevent this difficult, Sr(thd)₂ have to be stored in a freezer. A study (by P. J. Soininen, E L Conference, 1996, p.148)₇ carried out to avoid this trouble, discloses a method of synthesizing Sr(thd)₂ in a source tube by flowing H(thd) gas into Sr metal in the source tube and then supplying the same to its reactor. This study shows a little improvement in the luminance and uniformity of SrS thin films.

When halide metal compounds are used as precursors, halogen ions are remained in an EL device as impurities thus deteriorating its function. Doping process of metal atoms into the host material also have the same difficulty as the growth of host materials since coordination metal compounds such as thd-compounds are used. As the metal ions serve as luminescent center elements in the phosphor layers, the emission wavelengths is directly influenced by the chemical-bonding environment of metal ions. Therefore, the luminescence depends on the impurities induced from the precursors or the environmental condition of metal ions such as crystallinity.

According to the study by E. Nykanen, et al. (Proc. 6th EL Conf., 1992, p. 199) on CaS.Pb blue-emitting material, an EL device is made by the ALD method by using the coordination compounds Ca(thd)₂ for Ca element, and Pb(thd)₂, Pb(dedtc)₂, PbCI₂, and PbBr₂ as Pb precursors. The use of Pb(dedtc)₂ as Pb precursors shows the best result, and luminance was maximum 2.5 cd/m² at 300 Hz. However, the use of Pb(thd)₂ exhibits poor results in doping uniformity, chromaticity and luminance.

### SUMMARY OF THE INVENTION

An object of the present invention is to provide a method of fabricating thin films of IIA-group, IIIA-group, IVA-group, transition, or inner-transition metal sulfides, selenides or oxides by ALD or CVD method using coordination metal compounds adducted with neutral ligands as precursors.

The inventive coordination metal compounds adducted with neutral ligands via lone pair electrons are not easily denatured by moisture, oxygen, etc. in the air, and improves the uniformity and reproducibility of thin films by ALD method The neutral ligands come apart from the coordination compound molecules within a reaction chamber at below reaction temperatures, and do not participated directly in the reaction.

Another object of the present invention is to provide a method of fabricating EL device using the above technique.

Additional features and advantages of the invention will be set forth in the following description, and in part will be apparent from the description, or may be learned by practice of the invention. The objectives and other advantages of the invention will be realized and attained by the structure particularly pointed out in the written description and claims hereof as well as the appended drawings.

To achieve the advantages of the present invention, as embodied and broadly described, the present invention discloses a method of fabricating polycrystalline thin films based on IIA-group, IIIA-group, or IVA-group, transition, or inner transition metal sulfides or selenides. These thin films are deposited by surface reaction and vapor phase reaction using coordination metal compounds adducted with neutral ligands via lone-pair electrons, and H₂S or H₂Se as precursors.

Another aspect of the present invention is a method of fabricating polycrystalline metal oxide thin films based on IIA-group, IIIA-group, or IVA-group, transition, or inner transition metal oxides by surface reaction and vapor reaction by using coordination metal compounds adducted with neutral ligands as one of precursors.

Still another aspect of the present invention is a method of fabricating phosphor films for an EL device. The phosphor layers comprise the host material selected from one of IIA-group (Mg, Ca, Sr, and Ba) metal sulfides or selenides, and the luminescent center selected from at least one of transition, and inner-transition metal sulfide or selenides. These phosphor layers are deposited by using coordination metal compounds adducted with neutral ligands and H₂Z (Z=S, Se) as precursors.

Still another aspect of the present invention is a method of fabricating an EL device of double insulating structure including at least one phosphor layer formed of IIA-group, IIA-group, IVA-group, transition, or inner-transition metal sulfides or selenides, and at least one insulating layer deposited thereon and/or therebelow, wherein at least one thin film is deposited by using coordination compounds adducted with neutral ligands and H₂Z (Z=S, Se) as precursors.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this specification, illustrate embodiments of the invention and together with the description serve to explain the principles of the drawings:

In the drawings FIG. 1 is a schematic view of deposition equipment employed for embodiment of the present invention;

FIGS. 2a to 2b depict graphically the Rutherford backscattering spectra (RBS) of thin films of a CaS:Pb EL device fabricated by using Pb(thd)₂ and Pb(thd)₂−L (L=ethylenediamines) as precursors, respectively;

FIGS. 3a to 3b depict graphically the luminance-voltage characteristics of thin films of CaS:Pb EL devices fabricated by using Pb(thd)₂ and Pb(thd)₂—L (L =ethylenediamines) as precursors, respectively; and

FIGS. 4a to 4c depict alternating-current (AC) driven thin film electroluminescent devices according to the present invention.

### DETAILED DESCRIPTION OF PREFERRED EMBODIMENT

Reference will now be made in detail to the preferred embodiments of the present invention, examples of which are illustrated in the accompanying drawings.

The present invention encompasses a method of fabricating thin films based on of IIA-group, IIIA-group, IVA-group, transition, or inner-transition metal sulfides or selenides by ALD or CVD method by using coordination metal compounds adducted with neutral ligands as precursors at operating pressure of 1×10⁻⁷ to 10 torr. The present invention also provides a method of depositing a phosphor layers of EL device with luminance by ALD or CVD method by using precursors adducted with neutral ligands selected from an amine group (NR₃, R=hydrogen, methyl, ethyl, or propyl), a diamine group (ethylenediamine, 1,3-diaminopropane, and 1,2-diaminopropane), and a triamine group [N-(2-aminoethyl)-1,3-propanediamine, and diethylenetriamine]) at operating pressure of 1×10⁻⁷ to 10 torr.

FIG. 1 is a schematic view of fabrication of good-quality thin films by ALD or CVD method. Reference numerals 11 to 15 denote valves which control supply of precursors and purge gas, and reaction temperature is controlled by heating elements 22 and thin films are formed on a substrate 21. Precursors are supplied through a gaseous source module, a liquid source module 40, and a solid source tube 30. Solid precursors 31 are heated by heating elements 22 and then supplied to reactor 20.

The ALD method is based on the surface chemical reactions on a substrate between precursors that are alternatively provided. At the CVD method, precursors are simultaneously provided and mostly decomposed in gaseous state to be deposited as thin films.

In case of the ALD method, doping a transition or rare earth metal (M′) into a host material consisted of at least one of II-VI compound semiconductor is carried out by the incorporation of metal sulfide (M′S) thin film into the II-VI compound such as metal sulfides at operating pressure of 1×10⁻⁷ to 10 torr. The composition and location of metal ions doped in the II-VI metal sulfide thin films are controlled by the number of repetitive growth cycle used for depositing heterogeneous thin films and their growth rate. According to the CVD method, precursors of luminescent center ions (dopants) are simultaneously injected in the step of growing host materials at operating pressure of 1×10⁻⁷ to 10 torr.

The principal object of using precursors adducted with neutral ligands in the fabrication of a CaS:Pb blue-emitting phosphor layer is to enhance the stability and reactivity of the coordination metal compounds. An EL device can be manufactured by using Ca(thd)₂Lₓ and Pb(thd)₂Lₓ(L=ethylenediamine), instead of Ca(thd)₂ and Pb(thd)₂ used normally for the growth of CaS:Pb thin films.

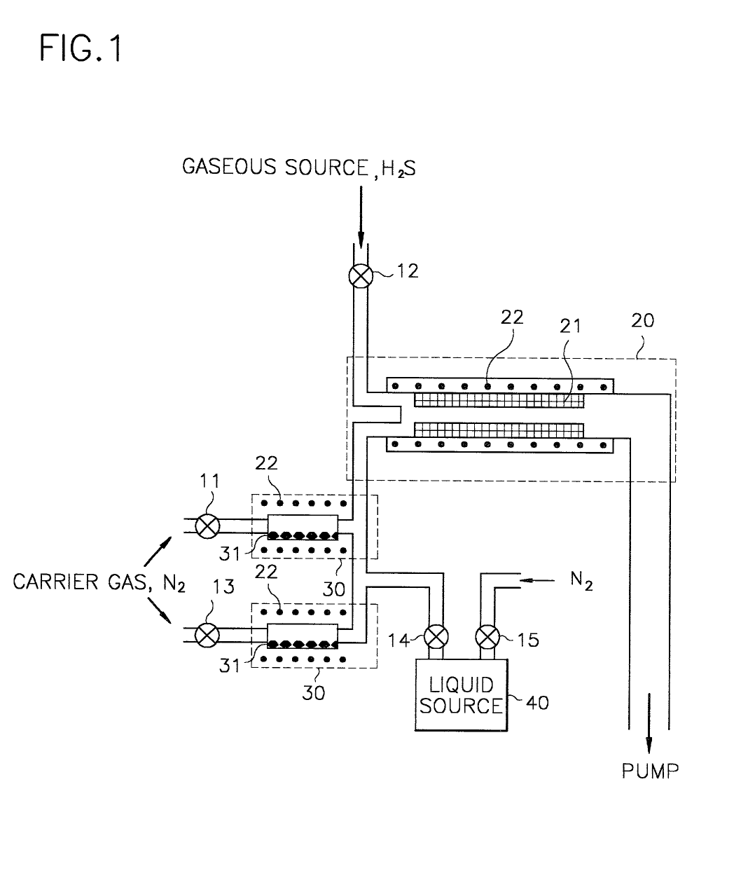

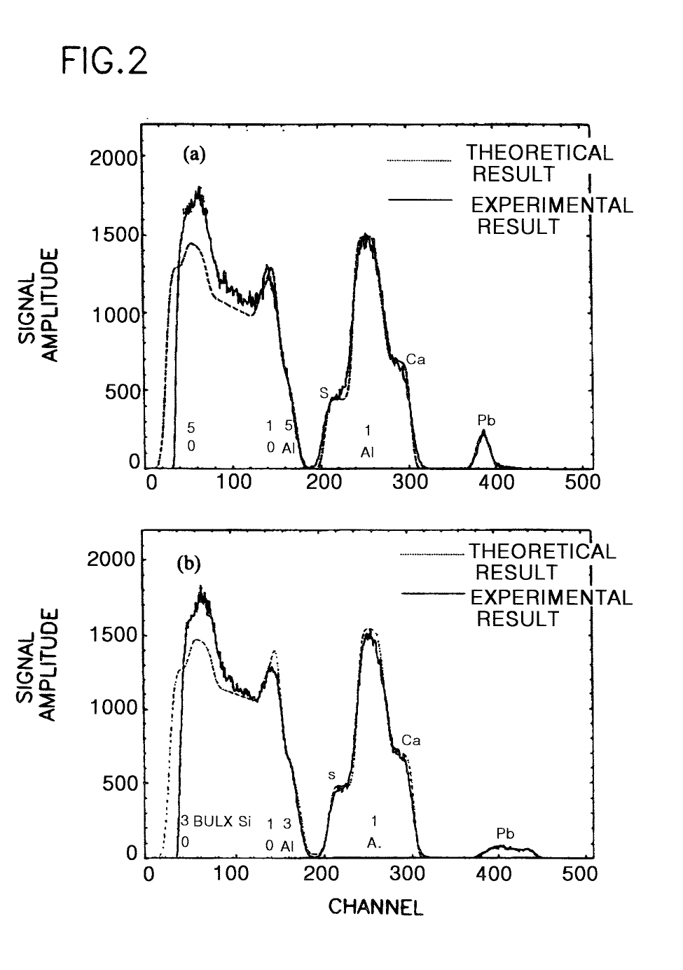

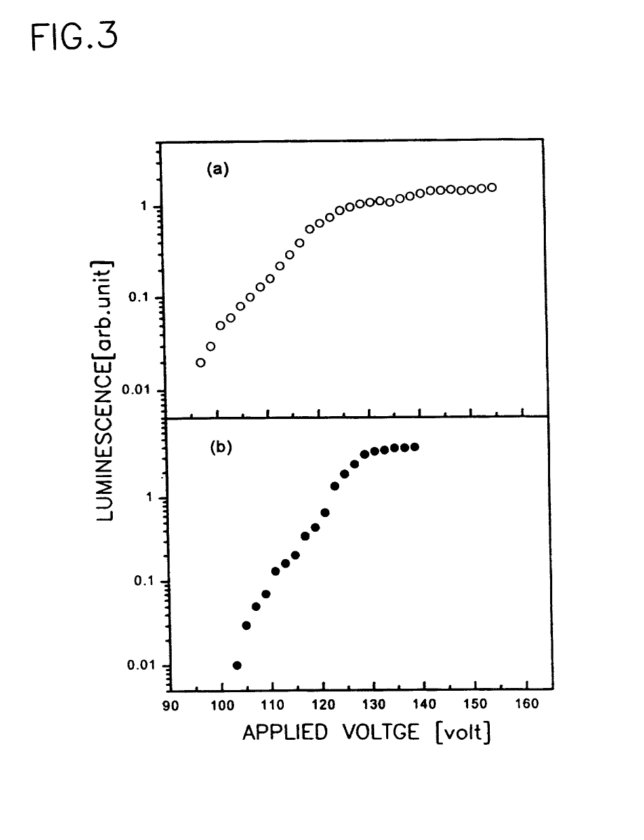

FIGS. 2a to 2b show RBS spectra of a CaS:Pb thin films deposited by using Pb(thd)₂ and Pb(thd)₂—L, as precursors, respectively. The distribution of Pb atoms is different as a function of the depth of thin films. When using Pb(thd)₂ (FIG. 2b), the Pb atoms are uniformly distributed with respect to the depth, and when using Pb(thd)₂—L, (FIG. 2a), most of the Pb atoms exist at deeper side of the thin films These results suggest that the characteristics of the precursors stabilized by neutral ligands during deposition are maintained and doping is uniformly carried out. However, when the precursors are not adducted with the neutral ligands, the characteristics of the precursors are changed during the reaction. That is because the Pb(thd)₂ precursors must be kept at about 200° C. during the process to grow CaS:Pb thin films with thickness about 3000 Å and they are denatured during that time. This degradation is also caused by the storage condition before charging the samples. FIGS. 3a and 3b show the luminance-voltage characteristics of CaS:Pb EL devices fabricated by using Pb precursors adducted with neutral ligands and other Pb precursors that are not adducted therewith, respectively. FIG. 3a relates to a CaS:Pb phosphor material made by using the Pb(thd)₂ precursors, and FIG. 3b concerns a CaS:Pb phosphor material containing the Pb(thd)₂—Lₓ. In comparison of the two cases in the luminance-voltage characteristics, when all other conditions are the same, the relative luminance is greatly increased when using Pb(thd)₂—Lₓ. In the use of the Pb(thd)₂ precursors the chromaticity (x, y) are as followings: x equals 0.22 to 0.29, and y equals 0.27 to 0.39. When using Pb(thd)₂—Lₓ. x equals 0.15 to 0.18, and y equals 0.11 to 0.15, the blue purity is significantly enhanced by utilizing the Pb(thd)₂—Lₓ precursors.

Since the latter assures the improved blue purity, it is not necessary to use a conventional filter any more to improve the blue purity, and a decrease in the luminance by the filter is prevented. The luminance in FIG. 3(b) is approximately 5 times higher than that of FIG. 3(b).

Sr(thd)₂ is decomposed if it is not stored at below −10° C., and it easily reacts with the moisture in the air and the surface of Sr(thd)₂ particles is significantly deteriorated when charging Sr(thd)₂ samples. While, the precursor adducted with neutral ligands, Sr(thd)₂—Lₓ, has not to be stored in a freezer, and is relatively stable in the air. Such characteristics allow to fabricate SrS thin films with excellent crystallinity and uniformities on the basis of thickness and concentration.

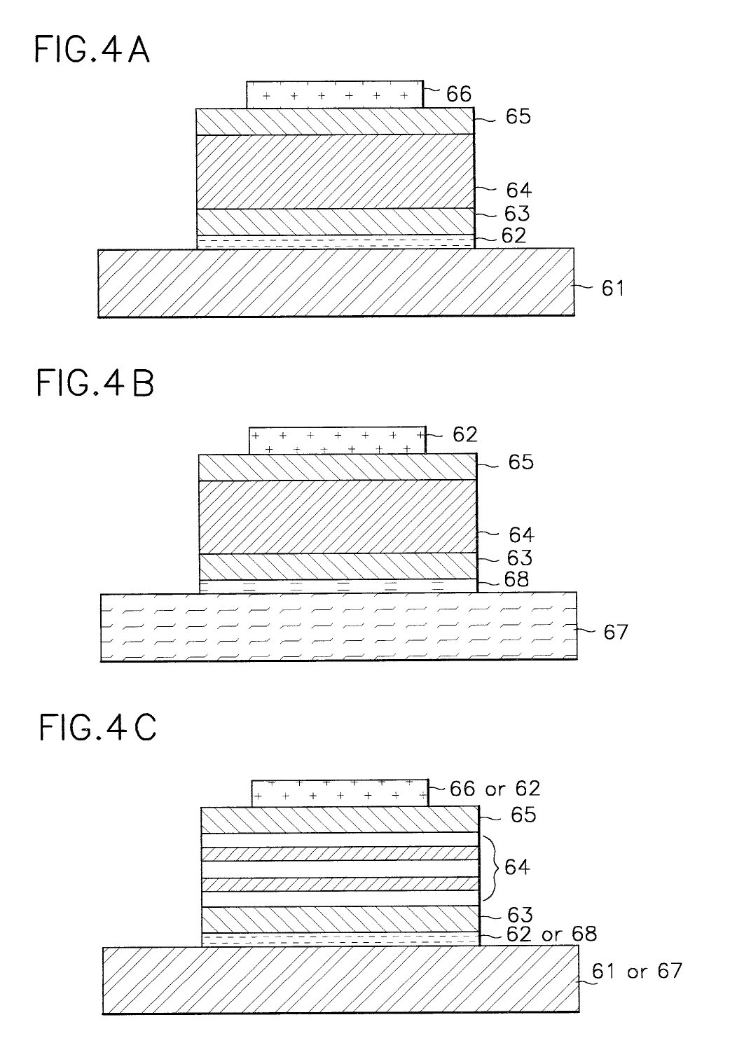

The phosphor material of the present invention may be utilized for fabrication of high luminance phosphor layers of three primary color or white color necessary for realizing the AC-driven full color ELDs. FIGS. 4a, 4b, and 4c each depict the basic ELD structure in accordance with the present invention.

FIG. 4a shows a normal structure grown on a transparent substrate 61, FIG. 4b is an inverted structure formed on opaque substrate 67, and FIG. 4c is a multilayered structure having phosphor layers formed of heterogeneous host materials. The structure of FIG. 4a is used for a simple monochromatic ELD, and includes a transparent electrode layer 62, a lower insulating layer 63, a phosphor layer 64, upper insulating layer 65, and a metal electrode layer 66 on transparent substrate 61.

The inverted structure of FIG. 4b is a model active-matrix ELD. As depicted in FIG. 4b, a refractory metal electrode layer 68, a lower insulating layer 63, phosphor layers 64, an upper insulating layer 65, and a transparent electrode 62 are formed on opaque substrate 67. The multilayered structure of FIG. 4c can use heterogeneous phosphor materials to be employed for multicolor-emitting ELDs. A transparent electrode layer 62 or refractory metal electrode layer 68, a lower insulating layer 63, heterogeneous phosphor layers 64, an upper insulating layer 65, and a transparent electrode layer 62 or a metal electrode 66 are formed on a transparent or opaque substrate 61 or 67. The AC-driven ELD is of double insulating structure having upper insulating layer 65 and lower insulating layer 63 that enclose phosphor layers 64, and these insulating layers protect phosphor layer against high electric field breakdown and outer environment and are formed of ZnS. As described above, the present invention provides a method of depositing metal compound thin films by the ALD or CVD method by using new coordination metal compounds adducted with neutral ligands as precursors, and a method of growing phosphor thin films for ELD. Such methods are used for a process of forming II-VI semiconductor host materials like CaS, SrS, BaS, MgS, etc. that are not easy to form thin films with good uniformity and reproducibility, and the process of doping IV-group, transition or inner-transition metal into these host materials.

In the process of forming CaS:Pb phosphor material, the phosphor material exhibits significantly enhanced luminance and blue purity by doping Pb ions on the host material, CaS, by using Pb(thd)₂—Lₓ(L=ethylenediamine), instead of Pb(thd)₂. Under the same conditions, the use of Ca(thd)₂—Lₓ displays more excellent EL characteristics than that of Ca(thd)₂. The inventive phosphor material exhibits more excellent reproducibility and uniformity than the conventional one, and is less sensitive to the storing condition. Since the adduct stabilizes precursors by coordination bonding, it is easy to store and handle samples, and it is advantageous to use.

The present invention relates to precursors of most host materials and doping elements of three primary color EL phosphor materials, and can be employed for ELDs. The process of fabricating three primary color phosphor materials does not need to use filters that lower the luminance, and is essential for development of high luminance ELDs. In addition, this may be used for fabrication of white-emitting EL material such as a multilayered structure of ZnS:Mn and CaS.Pb. The intensity of the emission is increased due to the enhancement of the crystallinity of phosphor layer.

Without changing the basic mechanism, the present invention increases the stability of the precursors during the deposition process since conventional metal coordination compounds are stabilized additional adducts with electron donor character.

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A method of fabricating polycrystalline thin films based on IIA-group, IIIA-group, IVA-group, transition, or inner-transition metal sulfides or selenides by surface reaction or vapor phase reaction by using coordination metal compounds, adducted with neutral ligands, and H₂Z (Z=S, Se) as precursors.

2. The method according to claim 1, wherein said coordination metal compounds are thd-coordination metal compounds (M(thd)ₙ—L_{y}, n=1 to 3, y=0.5 to 3, thd=2,2′,6,6′-tetramethyl-3,5-heptandione) and said neutral ligands are based on amines.

3. The method according to claim 2, wherein said neutral ligands are amine ligands (L=NR₃, R=one selected from the group of H, methyl, ethyl, and propyl).

4. The method according to claim 2, wherein said neutral ligands are diamine ligands (L=one selected from ethylenediamine, 1,3-diaminopropane, and 1,2-diaminopropane).

5. The method according to claim 2, wherein said neutral ligands are triamine ligands (L=one selected from the group of N(2-aminoethyl)-1,3-propanediamine, and diethylenetriamine).

6. The method according to claim 1, wherein said coordination metal compounds are dedtc-coordination metal compounds (M(dedtc)ₙ—L_{y}, n=1 to 3, y=0.5 to 3, dedtc=diethyldithiocarbamate) and said neutral ligands are based on amines (the number of contained N=1 to 3).

7. The method according to claim 1, wherein said metal sulfides or selenides polycrystalline thin films are grown by ALD method at an operating pressure of 1×10⁻⁷ to 10 torr.

8. The method according to claim 1, wherein said metal sulfides or selenides polycrystalline thin films are grown by a CVD method at an operating pressure of 1×10⁻⁷ to 10 torr

9. A method of fabricating polycrystalline thin films based on IIA-group, IIIA-group, IVA-group, transition, or inner-transition metal oxide by surface reaction or vapor phase reaction by using coordination metal compounds, adducted with neutral ligands, and H₂O as precursors.

10. A method of fabricating phosphor layer of an electroluminescent (EL) device, which consists of a host material selected at least one from IIA-group (Mg, Ca, Sr, and Ba) metal sulfides or selenides, and of the luminescent center element (IIIA-group, IVA-group, transition, inner-transition metal sulfides or selenides), by using coordination metal compounds adducted with neutral ligands and H2Z (Z=S, Se) as precursors.

11. The method according to claim 10, wherein said phosphor layer is MZ (M=one selected from the group of Ca, Sr, and Ba; Z=S, Se) polycrystalline phosphor films, said coordination metal compounds are M(thd)₂—L_{y}(y=0.5 to 3), and said neutral ligands are based on amines (L=one selected from the group of NR₃(R=one selected from the group of H, methyl, ethyl, and propyl), ethylenediamine, 1,3-diaminopropane, 1,2-diaminopropane, N-(2-aminoethyl)-1,3-propanediamine, and diethylenetriamine).

12. The method according to claim 11, wherein said phosphor films are fabricated by ALD method at an operating pressure of 1×10⁻⁷ to 10 torr.

13. The method according to claim 11, wherein said phosphor films are fabricated by CVD method at an operating pressure of 1×10 ⁻⁷ to 10 torr.

14. The method according to claim 1 1, wherein said polycrystalline phosphor films are CaS polycrystalline phosphor films, said coordination metal compounds are Ca(thd)₂—L_{y}(y=0.5 to 3), and H₂S are used as precursors.

15. The method according to claim 14, wherein said polycrystalline phosphor films are CaS:Pb (Pb=0.1 to 2 at.%) phosphor films, and said coordination compounds are Pb(thd)₂—L_{y}(y=0.5 to 3).

16. The method according to claim 11, wherein said polycrystalline phosphor films are SrS polycrystalline phosphor films, and said coordination compounds are Sr(thd)₂—L_{y}(y=0.5 to 3), and H₂S are used as precursors.

17. The method according to claim 16, wherein said polycrystalline phosphor films are SrS:Pb (Pb=0.1 to 2 at.%) phosphor films, and said coordination compounds are Pb(thd)₂—L_{y}(y=0.5 to 3).

18. The method according to claim 16, wherein said polycrystalline phosphor films are SrS:Ce (Ce=0.1 to 2 at.%) phosphor films, and said coordination compounds Ce(thd)₃—L_{y}(y=0.5 to 3).

19. The method according to claim 10, wherein said phosphor films are fabricated by adding one selected from the group of IIIA-group, IVA-group, transition, and inner-transition metal sulfides serving as a luminescent center element into the host material of MS (M=one selected from the group of Ca, Sr, and Ba) polycrystalline phosphor films with a concentration of 0.1 to 2 at.%, said neutral ligands are amine ligands (L=one selected from the group of NR₃(R=one selected from the group of H, methyl, ethyl, and propyl), ethylenediamine, 1,3-diaminopropane, 1,2-diaminopropane, N-(2-aminoethyl)-1,3-propanedianiine, and diethylenetriamine), and H₂S are used as precursors.

20. The method according to claim 19, wherein said phosphor films are fabricated by ALD method at an operating pressure of 1×10⁻⁷ to 10 torr.

21. The method according to claim 19, wherein said phosphor films are fabricated by CVD method at an operating pressure of 1×10⁻⁷ to 10 torr.

22. The method according to claim 10, wherein said host material is formed of a heterogeneous structure or a multilayered structure consisting of at least two of metal sulfides of the IIA-group (Ma, Ca, Sr and Ba), said host material including at least one of transition metal sulfides and IVA-group metal sulfides as a luminescent center element.

23. A method of fabricating an electroluminescent (EL) device of double insulating structure including at least one phosphor layer formed of IIA-group, IIIA-group, IVA-group, transition, or inner-transition metal sulfides or selenides, and at least one insulating layer formed thereon and/or therebelow, wherein at least one thin film is formed by using coordination compounds adducted with neutral ligands and H₂Z (Z=S, Se) as precursors.

24. A method according to claim 23, wherein said double insulating structure further includes at least one layer of ZnS for enhancing crystal property and for protecting the phosphor layer from the outer environment.
